(19) United States
(12) Patent Application Publication
(10) Pub. No.: US 2024/0162149 A1
(43) Pub. Date: May 16, 2024

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventors: Ji Seong KIM, Icheon-si Gyeonggi-do (KR); Yoon Ho KANG, Icheon-si Gyeonggi-do (KR); Wan Sup SHIN, Icheon-si Gyeonggi-do (KR); Seok Min JEON, Icheon-si Gyeonggi-do (KR)

(73) Assignee: SK hynix Inc., Icheon-si Gyeonggi-do (KR)

(21) Appl. No.: 18/318,480

(22) Filed: May 16, 2023

(30) Foreign Application Priority Data
Nov. 10, 2022 (KR) 10-2022-0149186

(51) Int. Cl. H01L 23/528; H01L 23/522; H10B 41/27; H10B 43/27

(52) U.S. Cl. CPC H01L 23/5283; H01L 23/5226; H10B 41/27; H10B 43/27

(57) ABSTRACT

A semiconductor device including: a gate structure in which conductive layers and insulating layers are alternately stacked; contact plug extending in a stacking direction of the insulating layers through the gate structure; first spacer layers each located between the conductive layer and the contact plug; and second spacer layers each located between the contact plug and the first spacer layer.

### CROSS-REFERENCE TO RELATED APPLICATION

This application claims priority under 35 U.S.C. § 119(a) to Korean Patent Application No. 10-2022-0149186 filed on Nov. 10, 2022, in the Korean Intellectual Property Office, which is incorporated herein by reference in its entirety.

### BACKGROUND

### 1. Technical Field

Embodiments of the present disclosure generally relate to an electronic device and a method of manufacturing the electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device including: a gate structure in which conductive layers and insulating layers are alternately stacked; a contact plug extending in a stacking direction of the insulating layers through the gate structure; first spacer layers each located between the conductive layer and the contact plug; and second spacer layers each located between the contact plug and the first spacer layer.

In an embodiment, a method of manufacturing a semiconductor device including: forming a stack including first material layers and second material layers that are alternately stacked; forming a first opening extending in a stacking direction of the first material layers through the stack; forming second openings connected to the first opening by etching the second material layers; forming first spacer layers in the second openings, respectively; forming second spacer layers in the second openings, respectively; and forming a contact plug in the first opening.

### BRIEF DESCRIPTION OF THE DRAWINGS

FIG. 1 is a diagram for describing a semiconductor device in accordance with an embodiment.

FIGS. 2A, 2B, 2C, and 2D are diagrams for describing a semiconductor device in accordance with an embodiment.

FIG. 3A and FIG. 3B are diagrams for describing a semiconductor device in accordance with an embodiment.

FIGS. 4A, 4B, 4C, 4D, 4E, 4F, 4G, and 4H are diagrams for describing a method of manufacturing a semiconductor device in accordance with an embodiment.

FIGS. 5A, 5B, 5C, 5D, 5E, 5F, 5G, 5H, 5I, and 5J are diagrams for describing a method of manufacturing a semiconductor device in accordance with an embodiment.

### DETAILED DESCRIPTION

Various embodiments are directed to a semiconductor device having a stable structure and improved characteristics and a manufacturing method thereof.

According to an embodiment, it may be possible to provide a semiconductor device having a stable structure and improved reliability.

Hereafter, embodiments in accordance with the technical spirit of the present disclosure will be described with reference to the accompanying drawings.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

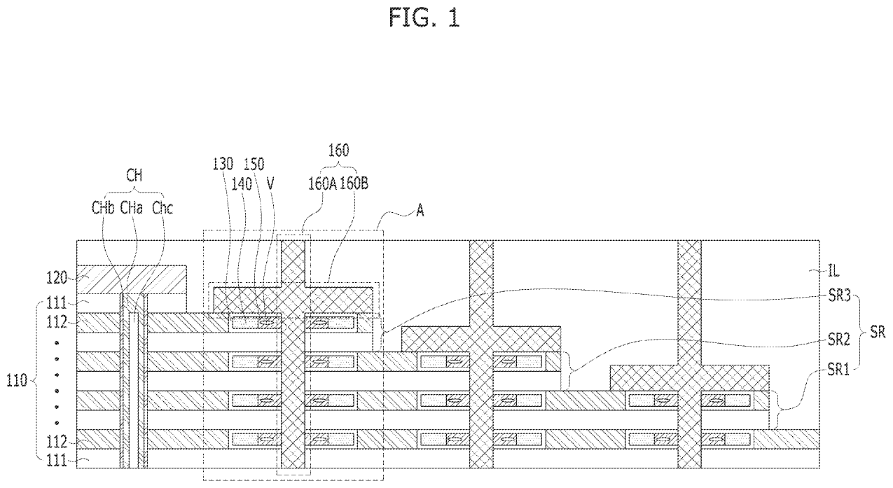

FIG. 1 is a diagram for describing a semiconductor device in accordance with an embodiment.

Referring to FIG. 1, the semiconductor device may include a gate structure 110, first spacer layers 140, second spacer layers 150, or contact plugs 160, or a combination thereof. The semiconductor device may further include a channel structure CH, a buffer layer 120, barrier layers 130, or an interlayer dielectric layer IL, or a combination thereof.

The gate structure 110 may include insulating layers 111 and conductive layers 112 that are alternately stacked. The insulating layers 111 may each include an insulating material such as oxide or nitride. The conductive layers 112 may each include a metal material such as tungsten. The conductive layers 112 may be word lines, bit lines, or select lines.

The gate structure 110 may include a step structure SR for exposing at least one of the conductive layers 112. The step structure SR may include at least one insulating layer 111 and at least one conductive layer 112. The step structure SR may include a first step structure SR1, a second step structure SR2, and a third step structure SR3. The uppermost conductive layer 112 among the conductive layers 112 included in the step structures SR1 to SR3 may be exposed by the step structure SR. In an embodiment, each first, second, and third step structure (i.e., SR1 to SR3) included in the step structure SR include at least two layers and the uppermost layer of the at least two layers (i.e., insulating layer 111 and conductive layer 112 for first step structure SR1) may be a conductive layer 112 which may be referred to herein as an uppermost conductive layer 112. For example, as illustrated in FIG. 1, the second step structure SR2 includes two layers, an insulating layer 111 and a conductive layer 112, the uppermost layer is the conductive layer 112 and may be referred to as the uppermost conductive layer 112. For example, as illustrated in FIG. 1, the third step structure SR3 includes two layers, an insulating layer 111 and a conductive layer 112, the uppermost layer is the conductive layer 112 and may be referred to as the uppermost conductive layer 112.

The contact plugs 160 may be electrically connected to the conductive layers 112. For example, each of the contact plugs 160 may be electrically connected to the uppermost conductive layer 112 of each of the step structures SR1 to SR3. The contact plug 160 may include a pillar 160A and a protrusion 160B protruding from the pillar 160A. The contact plug 160 may pass through the gate structure 110. The contact plug 160 may extend through the gate structure 110 in the stacking direction of the insulating layers. The pillar 160A may pass through the uppermost conductive layer 112 exposed by the step structure SR. The pillar 160A may also extend into the gate structure 110 and into the interlayer dielectric layer IL. The protrusion 160B may be connected to a top surface of the uppermost conductive layer 112 exposed by the step structure SR. The contact plug 160 may include a conductive material such as tungsten.

Although not illustrated in FIG. 1, each of the contact plugs 160 may also be connected to a peripheral circuit located below the gate structure 110 by passing through the gate structure 110. FIG. 1 illustrates that each of the contact plugs 160 passes through the interlayer dielectric layer IL and the gate structure 110; however, the present disclosure is not limited thereto and each of the contact plugs 160 may pass through only some of the conductive layers 112.

The first spacer layers 140 may each be located between the contact plug 160 and the conductive layer 112. The first spacer layers 140 may be located at levels corresponding to the levels of the conductive layers 112. The first spacer layers 140 may surround portions of sidewalls of the contact plugs 160. For example, each of the first spacer layers 140 may surround a part of the pillar 160A of the contact plug 160.

The first spacer layers 140 may insulate the contact plug 160 from the remaining conductive layers 112 except for the conductive layer 112 electrically connected to the contact plug 160. Accordingly, the first spacer layers 140 may prevent, minimize, or reduce the occurrence of bridges between the conductive layers 112 and the contact plug 160. The first spacer layers 140 may each include an insulating material such as oxide, silicon oxide, or nitride. The first spacer layers 140 may each include silicon oxide.

The second spacer layers 150 may each be located between the contact plug 160 and the first spacer layer 140. The second spacer layers 150 may be located at levels corresponding to the levels of the conductive layers 112. The second spacer layers 150 may surround portions of the sidewalls of the contact plugs 160. For example, each of the second spacer layers 150 may surround a part of the pillar 160A of the contact plug 160.

The second spacer layers 150 may insulate the contact plug 160 from the remaining conductive layers 112 except for the conductive layer 112 electrically connected to the contact plug 160. Accordingly, the second spacer layers 150 may prevent, minimize, or reduce the occurrence of bridges between the conductive layers 112 and the contact plug 160. The second spacer layers 150 may each include an insulating material such as oxide, silicon oxide, or nitride. The second spacer layers 150 may each include silicon oxide.

At least one of the second spacer layers 150 may include a void V. In an embodiment, a void V is caused in the process of forming the second spacer layers 150 and may be an empty space not filled with materials of the second spacer layers 150. The sizes of the voids V included in the second spacer layers 150 may be uniform or non-uniform. However, the present disclosure is not limited thereto, and the second spacer layers 150 may each include no void V.

Each of the barrier layers 130 may surround the first spacer layer 140 and the second spacer layer 150. Each of the barrier layers 130 may be located between the conductive layer 112 and the first spacer layer 140. The barrier layer 130 may extend between the first spacer layer 140 and the insulating layer 111 or may extend between the first spacer layer 140 and the protrusion 160B. The barrier layer 130 may have a C-shaped cross section, and the first spacer layer 140 and the second spacer layer 150 may be located in the barrier layer 130. The barrier layers 130 may each include an insulating material such as oxide or nitride.

The channel structure CH may pass through the gate structure 110. The channel structure CH may extend in the stacking direction of the insulating layers through the gate structure 110. The channel structure CH may include a channel layer CHa, and may further include at least one of a memory layer CHb surrounding a sidewall of the channel layer CHa and an insulating core CHc within the channel layer CHa. The channel layer CHa may include a semiconductor material such as silicon or germanium. The memory layer CHb may include a blocking layer, a data storage layer, or a tunneling layer, or a combination thereof. The data storage layer may include a floating gate, a polysilicon layer, a charge trap material, a nitride layer, a variable resistance material, or the like. The insulating core CHc may include an insulating material such as oxide, nitride, or an air gap.

The buffer layer 120 is a layer remaining in the manufacturing process of the semiconductor device and may be located on the channel structure CH. The buffer layer 120 may be configured as a single layer or a multilayer. The buffer layer 120 may include an insulating material such as oxide or nitride. For example, the buffer layer 120 may be configured as a single layer including SiCN or oxide, or a multilayer including a combination thereof.

Although not illustrated in FIG. 1, the semiconductor device may further include a support. The support may prevent, minimize, or reduce inclination of the gate structure 110 when the conductive layers 112 or the contact plugs 160 are formed during the manufacturing process. The support may include an insulating material such as oxide.

According to the structure described above, in an embodiment, the first spacer layers 140 and the second spacer layers 150 may be located between the conductive layers 112 and the contact plugs 160. In an embodiment, by placing a plurality of the spacer layers 140 and 150 between the conductive layers 112 and the contact plugs 160, it may be possible to prevent, minimize, or reduce the occurrence of bridges between the conductive layers 112 and the contact plug 160.

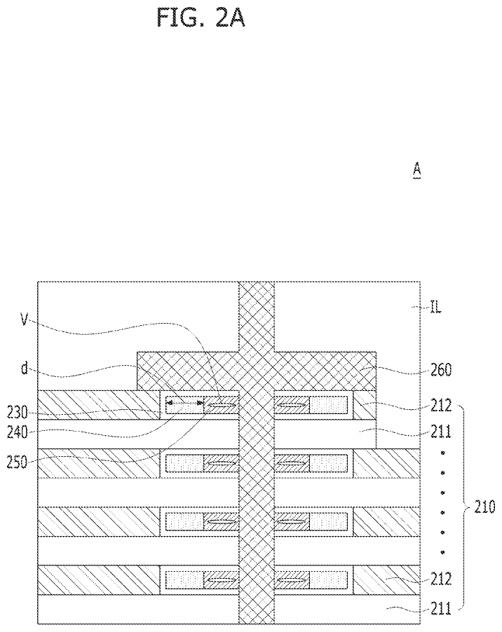

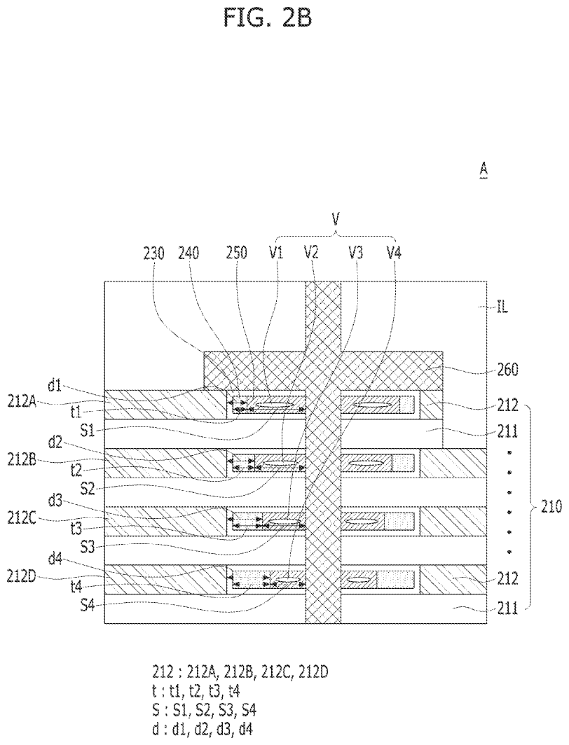

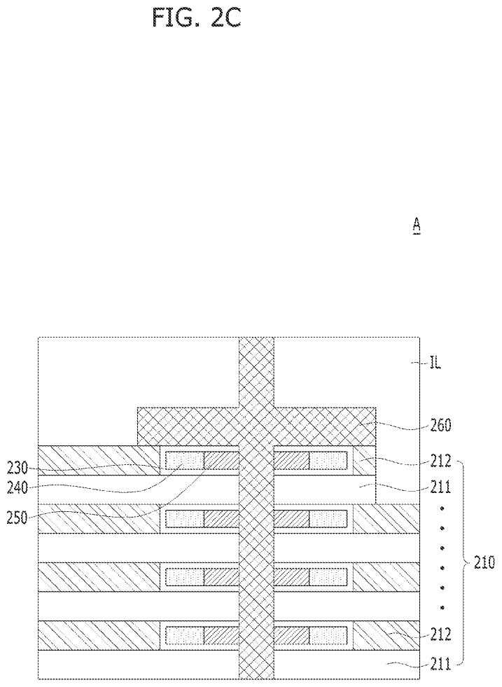

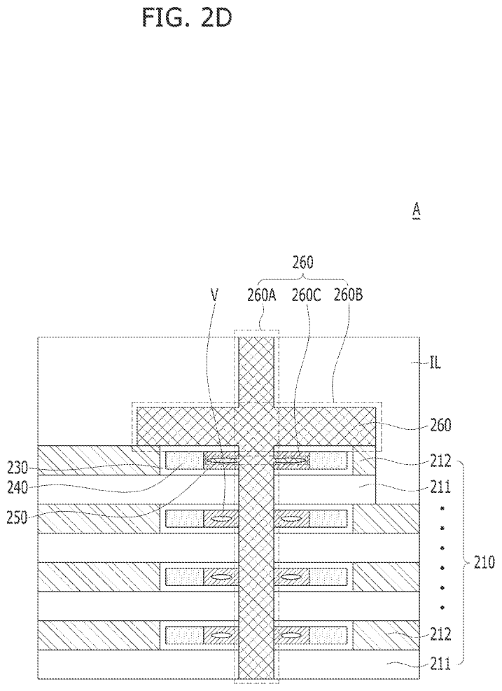

FIG. 2A to FIG. 2D are diagrams for describing a semiconductor device in accordance with an embodiment. FIG. 2A to FIG. 2D may be enlarged views of part A in FIG. 1. Hereinafter, the content overlapping with the previously described content will be omitted.

Referring to FIG. 2A, the semiconductor device may include a gate structure 210, first spacer layers 240, second spacer layers 250, or a contact plug 260, or a combination thereof. The semiconductor device may further include barrier layers 230 or an interlayer dielectric layer IL, or a combination thereof.

The contact plug 260 may pass through the interlayer dielectric layer IL and be electrically connected to an uppermost conductive layer 212. The contact plug 260 may include a conductive material such as tungsten.

The spacer layers 240 and 250 may be located between conductive layers 212 and the contact plug 260. The spacer layers 240 and 250 may insulate the conductive layers 212 and the contact plug 260 from each other. When the spacer layers 240 and 250 include voids V, bridges may occur between the conductive layers 112 and the contact plug 260 during a manufacturing process of the semiconductor device. At least one of the spacer layers 240 and 250 may include the voids V. For example, the first spacer layers 240 may include no voids V, and at least one of the second spacer layers 250 may include the void V. Even though each of the second spacer layers 250 includes the void V, the first spacer layer 240 including no void V is located between the second spacer layer 250 and the conductive layer 212, so that it may be possible to secure a distance d between the conductive layer 212 and the void V. Accordingly, in an embodiment, the first spacer layers 240 may prevent, minimize, or reduce the occurrence of bridges between the conductive layers 212 and the contact plug 260.

Whether the spacer layers 240 and 250 include the voids V may be determined according to a formation method thereof. The spacer layers 240 and 250 may be formed by an oxidation method or a deposition method. When the spacer layers 240 and 250 are formed by an oxidation method, the spacer layers 240 and 250 may include no voids V, and when the spacer layers 240 and 250 are formed by a deposition method, the spacer layers 240 and 250 may include the voids V. For example, the first spacer layers 240 may be layers formed by an oxidation method and may be void-free oxide layers each including no void V. The second spacer layers 250 may be layers formed by a deposition method and may include the void V. The sizes of the voids V included in the spacer layers 240 and 250 may be uniform or non-uniform.

Referring to FIG. 2B, thicknesses t of the first spacer layers 240 may be substantially the same as or different from each other. For example, the first spacer layers 240 located at different levels may have different thicknesses t1 to t4. The thickness t1 of the first spacer layer 240 located at a level corresponding to the level of a conductive layer 212A may be smaller than the thickness t2 of the first spacer layer 240 located at a level corresponding to the level of a conductive layer 212B.

Thicknesses s of the second spacer layers 250 may be substantially the same as or different from each other. For example, the second spacer layers 250 located at different levels may have different thicknesses s1 to s4. The thickness s1 of the second spacer layer 250 located at a level corresponding to the level of the conductive layer 212A may be greater than the thickness s2 of the second spacer layer 250 located at a level corresponding to the level of the conductive layer 212B.

The sizes of the voids V included in the second spacer layers 250 may be substantially the same as or different from each other. For example, the size of a void V1 may be greater than that of a void V2.

As the sizes of the voids V1 to V4 included in the second spacer layers 250 respectively increase, the probability of the occurrence of bridges between the conductive layers 212 and the contact plug 260 may increase. For example, when the size of the void V2 is greater than the size of the void V1, the conductive layer 212B may be electrically connected to the contact plug 260 during the manufacturing process, and bridges may occur. In order to prevent such bridges, the first spacer layer 240 including no void V may be located between the conductive layer 212 and the second spacer layer 250.

Therefore, since the first spacer layers 240 including no voids V exist, distances d between the voids V of the second spacer layers 250 and the conductive layers 212 may be secured by the thicknesses t of the first spacer layers 240. For example, distances d1 to d4 between the voids V and the conductive layers 212 may be substantially the same as or different from one another.

Referring to FIG. 2C, the first spacer layers 240 and the second spacer layers 250 may include no voids V. The first spacer layers 240 and the second spacer layers 250 may be formed in substantially the same manner or in different manners. For example, the first spacer layers 240 may be formed by an oxidation method, and the second spacer layers 250 may be formed by a deposition method. As another example, the first spacer layers 240 and the second spacer layers 250 may be formed by an oxidation method. In other words, the spacer layers 240 and 250 may be formed as void-free oxide layers. An interface may exist between the first spacer layer 240 and the second spacer layer 250 formed through a separate process.

Referring to FIG. 2D, the first spacer layers 240 may include no voids, and each of the second spacer layers 250 may include a void V. In such a case, during the manufacturing process, some of the voids V of the second spacer layers 250 may be exposed and the contact plug 260 including a plurality of protrusions 260B and 260C may be formed. For example, a first protrusion 260B of the contact plug 260 connected to the top surface of the uppermost conductive layer 212 exposed by a step structure may be formed. Furthermore, a second protrusion 260C located in the second spacer layer 250 and protruding from a pillar 260A may be formed. However, the present disclosure is not limited thereto, and even though the void V is exposed in the manufacturing process, the second protrusion 260C might not be formed.

According to the structure described above, even though each of the second spacer layers 250 includes a void V, the first spacer layers 240 may include no voids V because they are formed by an oxidation process. Therefore, in an embodiment, by securing the distances d between the conductive layers 212 and the voids V by the thicknesses t of the first spacer layers 240, it may be possible to prevent, minimize, or reduce the occurrence of bridges between the conductive layers 212 and the contact plug 260.

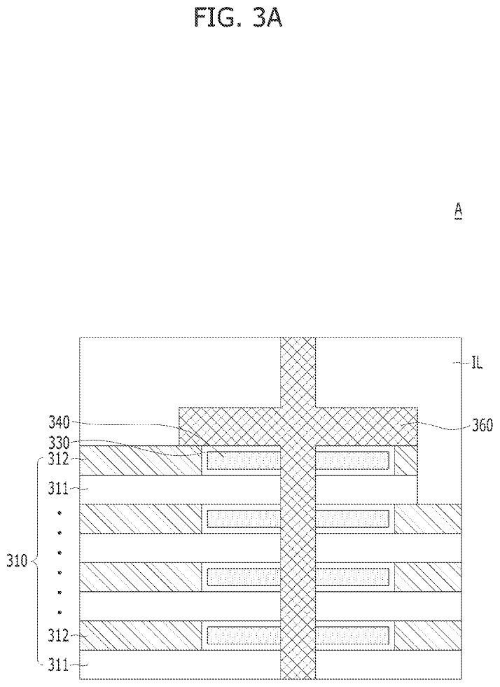

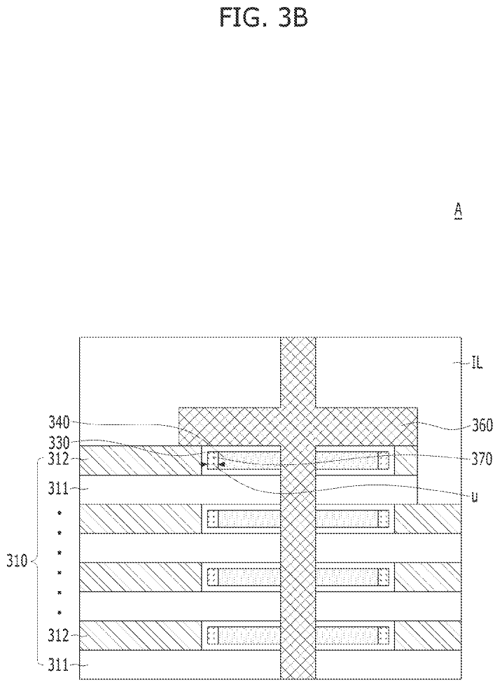

FIG. 3A and FIG. 3B are diagrams for describing a semiconductor device in accordance with an embodiment. FIG. 3A and FIG. 3B may be enlarged views of part A in FIG. 1. Hereinafter, the content overlapping with the previously described content will be omitted.

Referring to FIG. 3A, the semiconductor device may include a gate structure 310, first spacer layers 340, or a contact plug 360, or a combination thereof. The semiconductor device may further include a barrier layer 330 or an interlayer dielectric layer IL, or a combination thereof.

The contact plug 360 may pass through the interlayer dielectric layer IL and be electrically connected to an uppermost conductive layer 312. The contact plug 360 may include a conductive material such as tungsten.

The first spacer layer 340 may be located between the contact plug 360 and the conductive layer 312. The first spacer layers 340 may be located at levels corresponding to the levels of the conductive layers 312 and may surround portions of sidewalls of the contact plugs 360. The first spacer layers 340 are formed by an oxidation process and may include no voids. Accordingly, the first spacer layer 340 may be located as a single layer including no void between the contact plug 360 and the conductive layer 312.

Referring to FIG. 3B, the semiconductor device may further include sacrificial layers 370. Each of the sacrificial layers 370 may be located between the first spacer layer 340 and the conductive layer 312. The sacrificial layers 370 and the conductive layers 312 may be located at levels corresponding to each other. The sacrificial layers 370 may remain without being replaced with the first spacer layers 340 during a manufacturing process of the semiconductor device. The thicknesses u of the remaining sacrificial layers 370 may be substantially the same as or different from each other. For example, the thicknesses u of the sacrificial layers 370 located at different levels may be different from each other. However, the present disclosure is not limited thereto, and the thicknesses u of the sacrificial layers 370 located at the same level may also be different from each other. The sacrificial layers 370 may each include silicon or the like. For example, the sacrificial layers 370 may each include amorphous silicon, polysilicon, or the like. The remaining sacrificial layer 370 may be located in the barrier layer 330 and may be electrically floated.

FIG. 3A and FIG. 3B illustrate only the first spacer layers 340; however, the present disclosure is not limited thereto and second spacer layers may be additionally located between the first spacer layers 340 and the contact plug 360, respectively.

According to the structure described above, the first spacer layers 340 formed by an oxidation process may be located between the contact plug 360 and the conductive layers 312, respectively. Accordingly, in an embodiment, the occurrence of bridges between the conductive layers 312 and the contact plug 360 may be prevented, minimized, or reduced by the first spacer layers 340 including no voids.

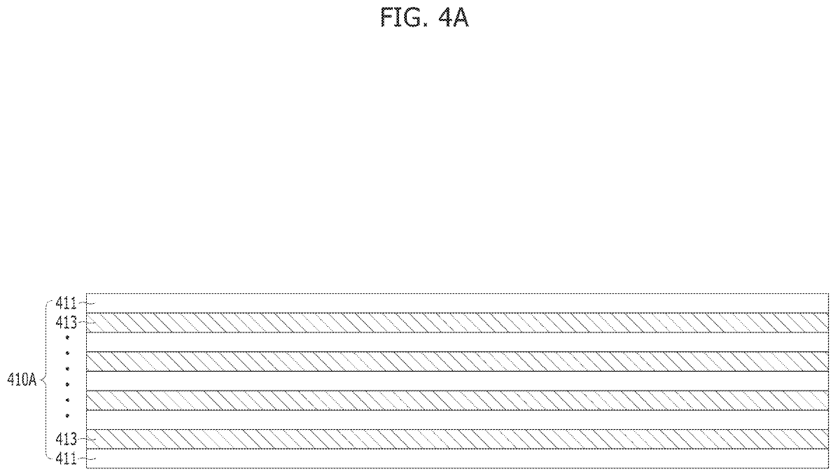

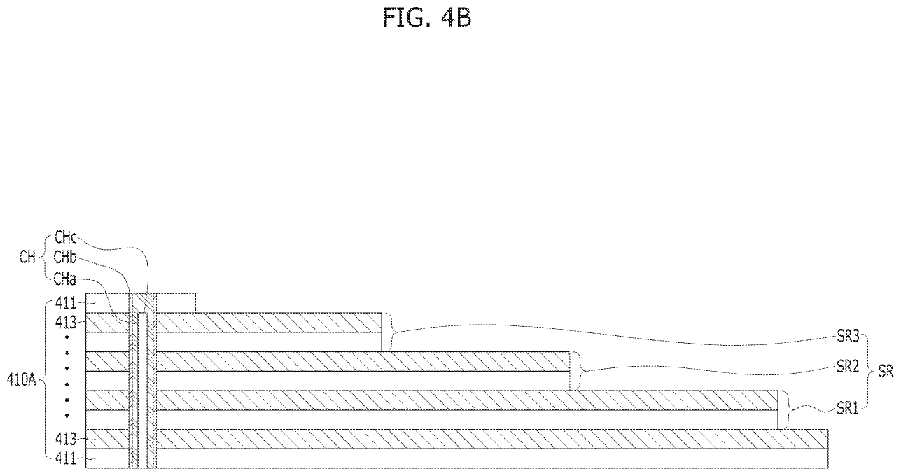

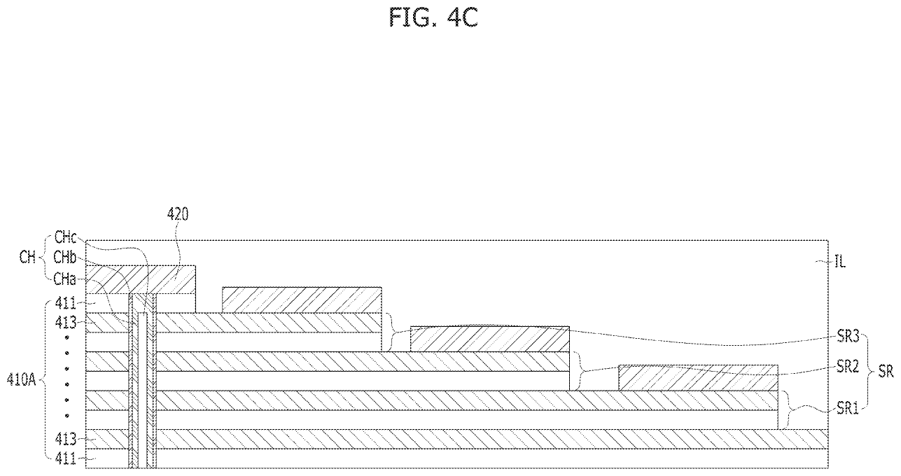

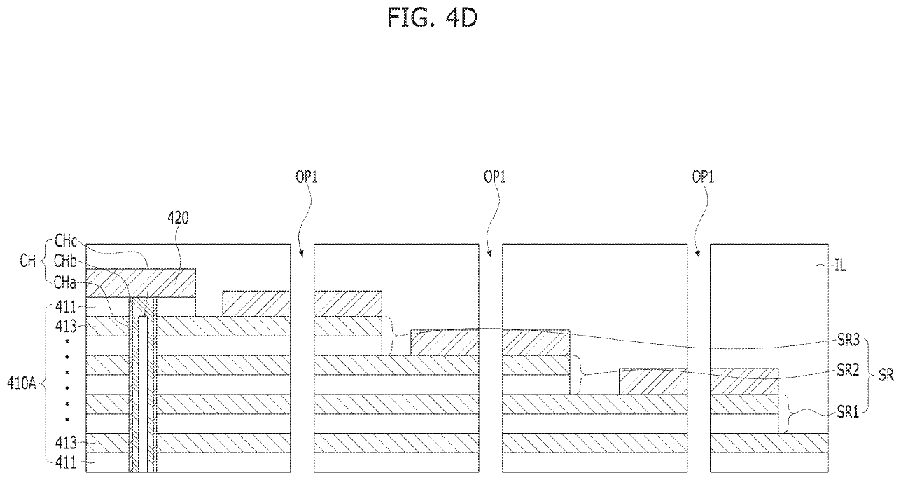

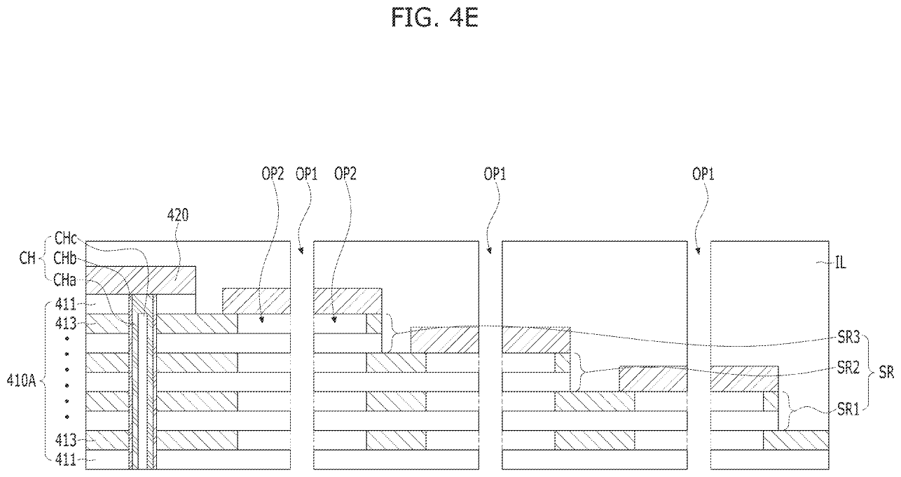

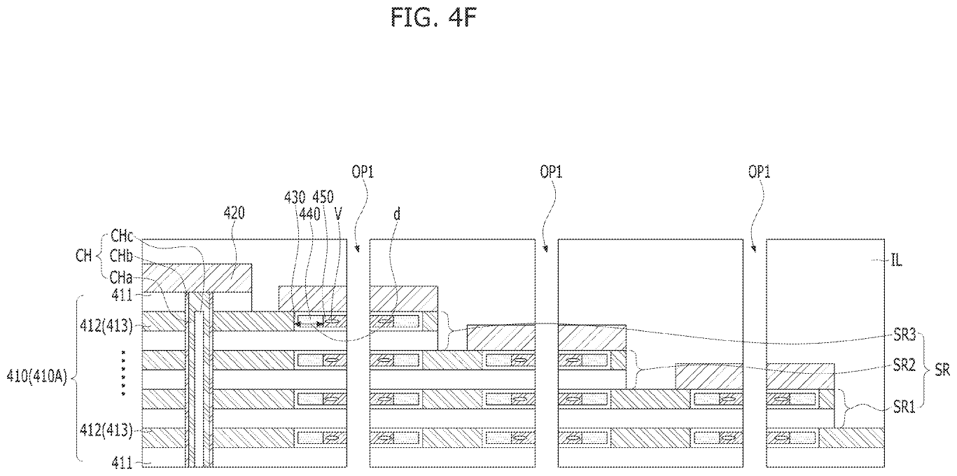

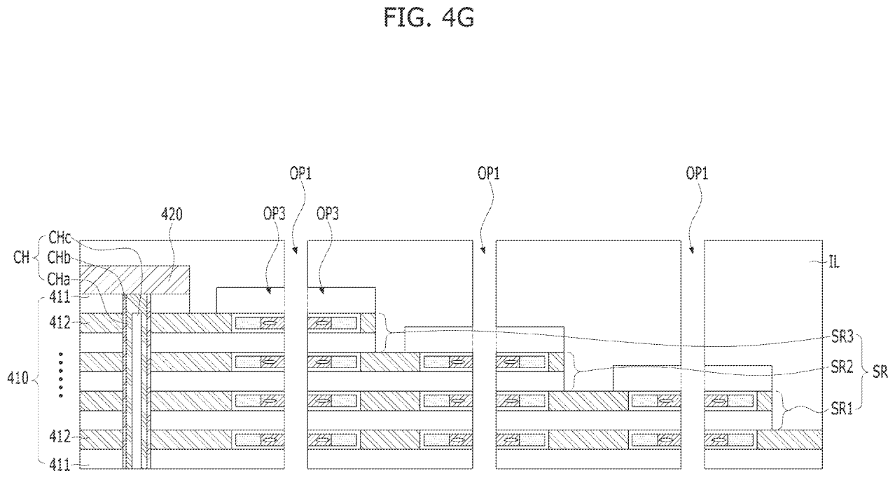

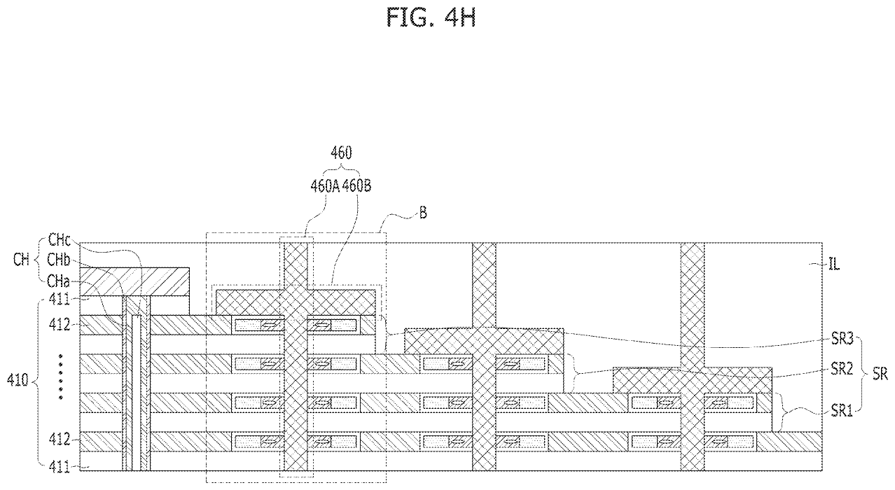

FIG. 4A to FIG. 4H are diagrams for describing a method of manufacturing a semiconductor device in accordance with an embodiment. Hereinafter, the content overlapping with the previously described content will be omitted.

Referring to FIG. 4A, a stack 410A may be formed. The stack 410A may include first material layers 411 and second material layers 413 that are alternately stacked. The first material layers 411 and the second material layers 413 may each include an insulating material such as oxide or nitride. As another example, the first material layers 411 may each include an oxide, and the second material layers 413 may each include a conductive material such as polysilicon, tungsten, or molybdenum.

Referring to FIG. 4B, a channel structure CH passing through the stack 410A may be formed. The channel structure CH extending in the stacking direction of the first material layers 411 through the stack 410A may be formed. The channel structure CH may include a channel layer CHa, and may further include at least one of a memory layer CHb surrounding a sidewall of the channel layer CHa and an insulating core CHc within the channel layer CHa.

Subsequently, a step structure SR for exposing at least one of the second material layers 413 may be formed. The step structure SR may include at least one first material layer 411 and at least one second material layer 413. The step structure SR may include a first step structure SR1, a second step structure SR2, and a third step structure SR3. The uppermost second material layer 413 of one or more second material layers 413 included in each of the step structures SR1 to SR3 may be exposed by the step structure SR.

Referring to FIG. 4C, a buffer layer 420 may be formed on the step structure SR. First, a buffer material may be formed along a profile of the step structure SR. Subsequently, the buffer material formed on a sidewall of the step structure SR may be removed. For example, since the buffer material formed on the sidewall of the step structure SR is thinner than the buffer material formed on a top surface of the step structure SR, an etching process may be performed so that the buffer material formed on the top surface of the step structure SR remains and the buffer material formed on the sidewall of the step structure SR is removed. Through this, the buffer layers 420 may be formed on the step structure SR.

Each of the buffer layers 420 is a sacrificial layer, and is used to form protrusions of contact plugs (not illustrated) to be described below. The buffer layer 420 may be a single layer or a multilayer. The buffer layer 420 may include an insulating material such as oxide or nitride. For example, the buffer layer 420 may be configured as a single layer including SiCN or oxide, or a multilayer including a combination thereof. Subsequently, an interlayer dielectric layer IL may be formed on the stack 410A.

Referring to FIG. 4D, first openings OP1 passing through the stack 410A may be formed. The first openings OP1 extending in the stacking direction of the first material layers 411 through the stack 410A may be formed. For example, the first openings OP1 may pass through the interlayer dielectric layer IL and the buffer layers 420 and extend into the stack 410A. The first openings OP1 may be formed to expose the uppermost second material layer 413 of one or more second material layers 413 included in each of the step structures SR1 to SR3.

Referring to FIG. 4E, second openings OP2 may be formed. For example, one or more second material layers 413 exposed through the first openings OP1 may be selectively etched. The second openings OP2 may be formed in regions where the second material layers 413 are etched. Through this, the second openings OP2 respectively connected to the first openings OP1 may be formed.

Referring to FIG. 4F, first spacer layers 440 may be formed. For example, the first spacer layers 440 may be formed in the second openings OP2, respectively. Subsequently, second spacer layers 450 may be formed in the second openings OP2, respectively. For example, the second spacer layers 450 may be formed in the first spacer layers 440, respectively. The spacer layers 440 and 450 may include or might not include voids V. For example, the first spacer layers 440 may each include no void V, and at least one of the second spacer layers 450 may include the void V. Since the second spacer layers 450 are formed after the first spacer layers 440 are formed, even though each of the second spacer layers 450 includes the void V, a distance d between the void V and the second material layer 413 may be secured by the first spacer layer 440. The first spacer layers 440 or the second spacer layers 450 may each include oxide. For example, the first spacer layers 440 or the second spacer layers 450 may each include silicon oxide.

Subsequently, the second material layers 413 may be replaced with third material layers 412, respectively. When the second material layers 413 are sacrificial layers, slits may be formed through the stack 410A, and the second material layers 413 may be removed through the slits. Subsequently, the third material layers 412 may be formed in regions where the second material layers 413 are removed. The third material layers 412 may be conductive layers and may each include a conductive material such as polysilicon, tungsten, or molybdenum. When the second material layers 413 are conductive layers, the third material layers 412 may be formed by performing a process for reducing resistance of the second material layers 413, such as a silicidation process. Thus, a gate structure 410 including the first material layers 411 and the third material layers 412 that are alternately stacked may be formed.

The barrier layers 430 may be first formed before the first spacer layers 440 are formed. The barrier layers 430 may each include an insulating material such as oxide or nitride.

Although not illustrated in FIG. 4F, a gap-fill layer may be formed in the first opening OP1 before the second material layer 413 is replaced with the third material layer 412. Subsequently, the second material layers 413 may be replaced with the third material layers 412, and the first openings OP1 may be formed.

Referring to FIG. 4G, third openings OP3 may be formed. For example, the third openings OP3 may be formed by removing the buffer layers 420 through the first openings OP1. Through this, the third openings OP3 respectively connected to the first openings OP1 may be formed. The buffer layer 420 formed on the channel structure CH may remain without being removed.

When the third openings OP3 are formed, the spacer layers 440 and 450 exposed through the first openings OP1 may be partially etched. For example, the void V included in at least one of the second spacer layers 450 is exposed, so that the second spacer layer 450 may be etched. However, the third material layers 412 might not be exposed by the first spacer layers 440 including no voids V.

Referring to FIG. 4H, a contact plug 460 may be formed in the first opening OP1. For example, the contact plug 460 may be formed in each of the first openings OP1. A pillar 460A of the contact plug 460 may be formed in the first opening OP1, and a protrusion 460B of the contact plug 460 may be formed in the third opening OP2. The pillar 460A may pass through the uppermost third material layer 412 exposed by the step structure SR. The protrusion 460B of the contact plug 460 may be connected to the top surface of the uppermost third material layer 412 of each of the step structures SR1 to SR3.

According to the process described above, the spacer layers 440 and 450 may be formed between the third material layers 412 and the contact plugs 460, respectively. By forming a plurality of the spacer layers 440 and 450, in an embodiment, it may be possible to prevent, minimize, or reduce the occurrence of bridges between the third material layers 412 and the contact plugs 460.

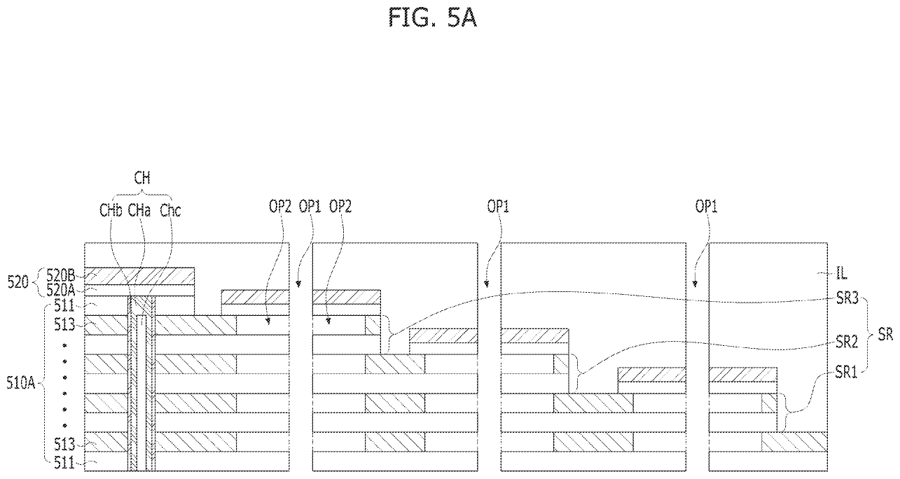

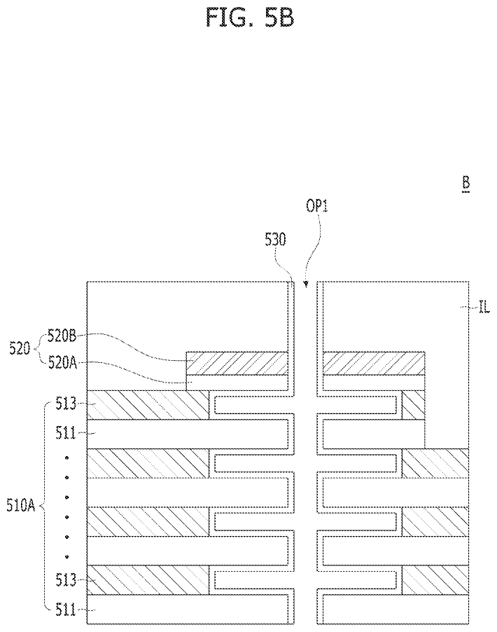

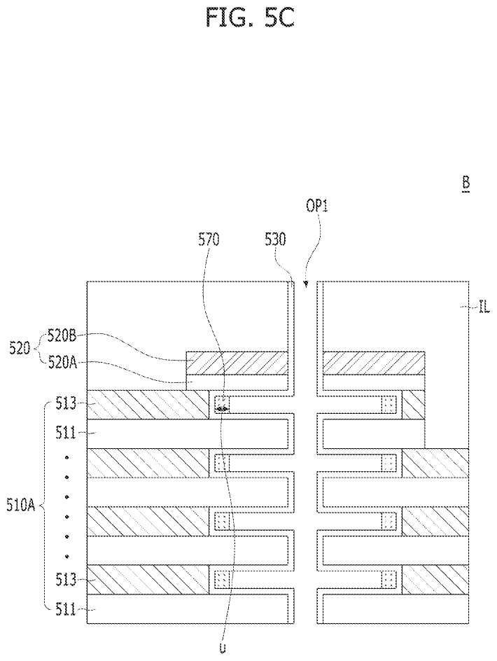

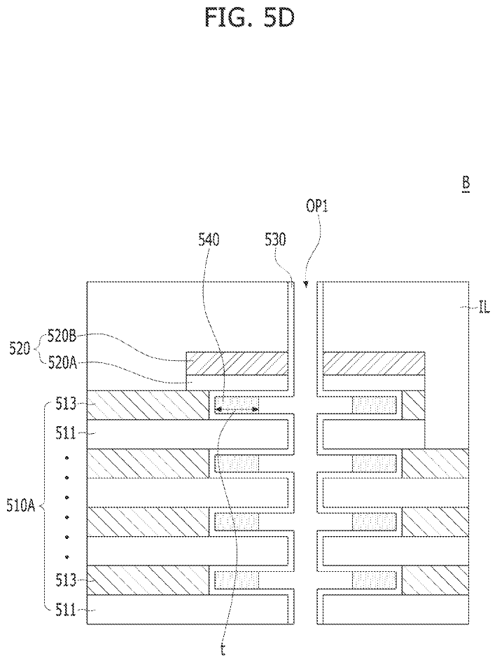

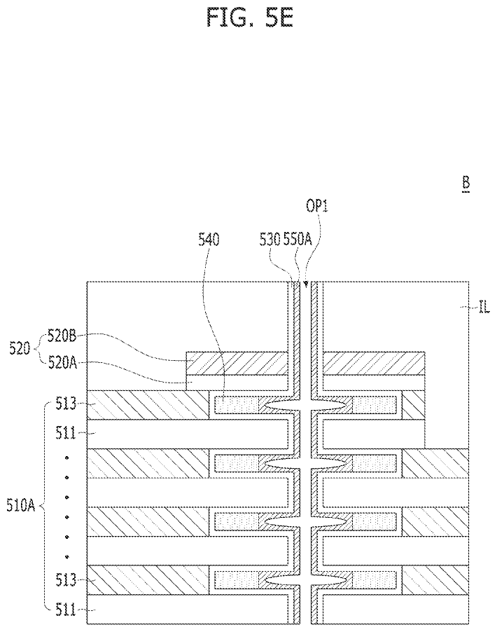

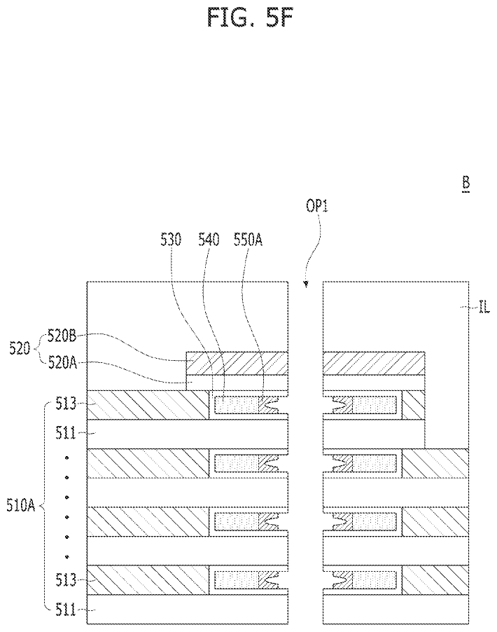

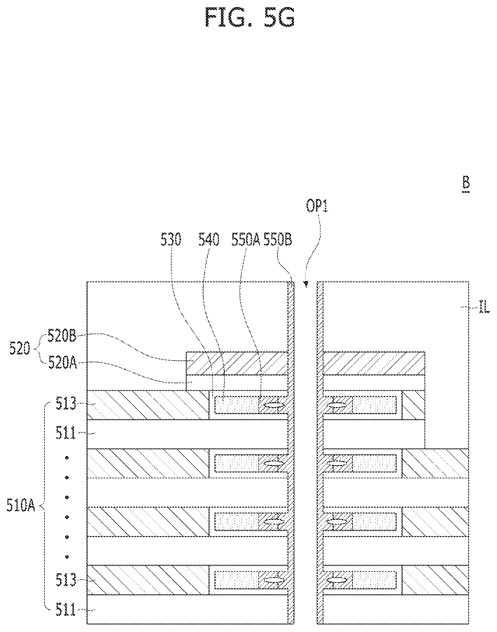

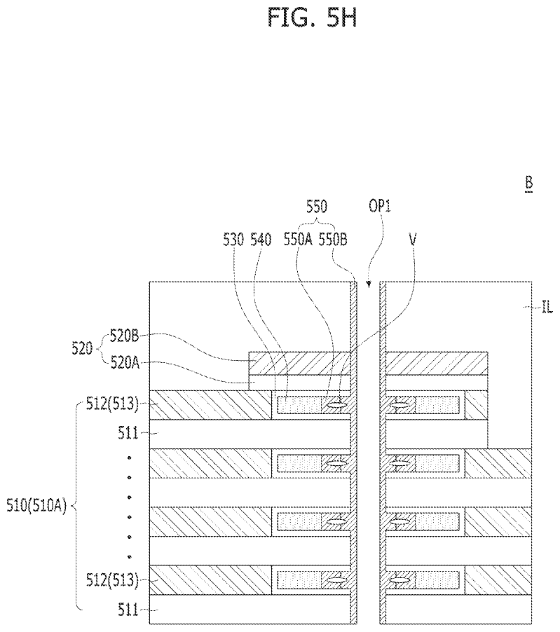

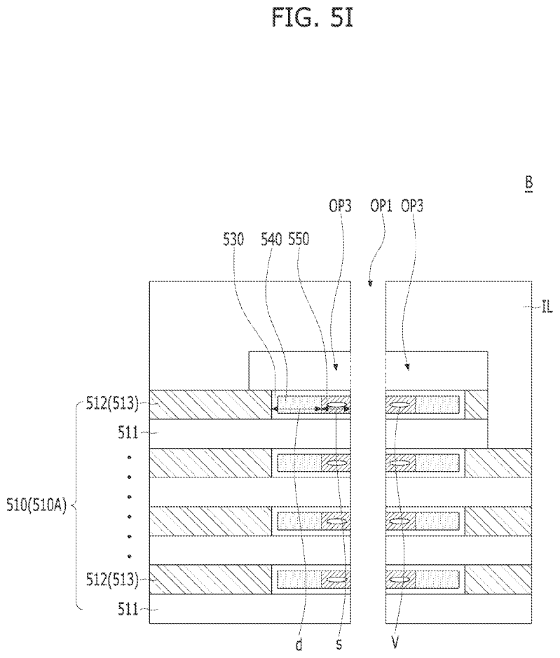

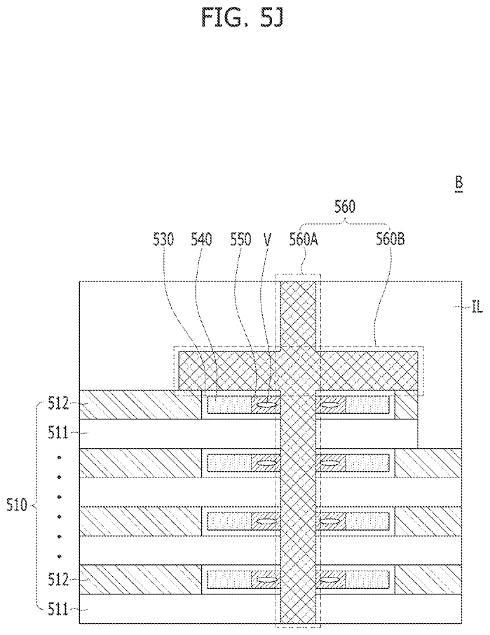

FIG. 5A to 5J are diagrams for describing a method of manufacturing a semiconductor device in accordance with an embodiment. Hereinafter, the content overlapping with the previously described content will be omitted.

Referring to FIG. 5A, a stack 510A including first material layers 511 and second material layers 513 that are alternately stacked may be formed, and a channel structure CH passing through the stack 510A may be formed. For example, the channel structure CH extending in the stacking direction of the first material layers 511 through the stack 510A may be formed. Subsequently, a step structure SR may be formed. For example, the step structure SR for exposing at least one of the second material layers 513 may be formed. The step structure SR may include a first step structure SR1, a second step structure SR2, and a third step structure SR3.

Subsequently, buffer layers 520 may be formed on the step structure SR. For example, first, a lower buffer material may be formed along a profile of the step structure SR. Subsequently, an upper buffer material may be formed on the lower buffer material. Subsequently, buffer materials formed on a sidewall of the step structure SR may be removed. For example, since the buffer materials formed on the sidewall of the step structure SR are thinner than the buffer materials formed on a top surface of the step structure SR, an etching process may be performed so that the buffer materials formed on the top surface of the step structure SR remain and the buffer materials formed on the sidewall of the step structure SR are removed. Thus, the buffer layer 520 including a lower buffer layer 520A and an upper buffer layer 520B may be formed. The lower buffer layer 520A may include oxide, and the upper buffer layer 520B may include SiCN.

Subsequently, an interlayer dielectric layer IL may be formed on the stack 510A. Subsequently, first openings OP1 passing the stack 510A may be formed. The first openings OP1 extending in the stacking direction of the first material layers 511 through the stack 510A may be formed. For example, the first openings OP1 may be formed so that the uppermost second material layer 513 among one or more second material layer 513 included in each of the step structures SR1 to SR3 is exposed. The first openings OP1 may extend into the interlayer dielectric layer IL or the stack 510A. Subsequently, second openings OP2 may be formed by partially removing the second material layers 513 exposed through the first openings OP1. For example, the second openings OP2 connected to the first opening OP1 may be formed by etching the second material layers 513.

Referring to FIG. 5B, a barrier layer 530 may be formed. For example, the barrier layer 530 may be formed in the first opening OP1 and the second openings OP2. The barrier layer 530 may insulate a sacrificial layer (not illustrated) and third material layers 512 from each other in a subsequent process. The barrier layer 530 may increase adhesion of first spacer layers 540 or second spacer layers 550 to be formed in a subsequent process. The barrier layer 530 may include an insulating material such as oxide or nitride. However, the present disclosure is not limited thereto, and subsequent processes may be performed without forming the barrier layer 530.

Referring to FIG. 5C, sacrificial layers 570 may be formed. For example, the sacrificial layers 570 may be formed in the second openings OP2, respectively. First, a sacrificial material may be formed in the first opening OP1 and the second openings OP2. Subsequently, the sacrificial material may be etched to remove a portion of the sacrificial material formed in the first opening OP1. In such a case, the sacrificial material formed in the second openings OP2 may also be partially etched. Thus, the sacrificial layers 570 remaining in the second openings OP2 may be formed. The thicknesses u of the sacrificial layers 570 may be substantially the same as or different from each other. For example, the thicknesses u of the sacrificial layers 570 located at different levels may be different from each other. The sacrificial layers 570 may each include silicon or the like. For example, the sacrificial layers 570 may each include amorphous silicon, polysilicon, or the like.

Referring to FIG. 5D, the first spacer layers 540 may be formed. For example, the first spacer layers 540 may be formed by oxidizing the sacrificial layers 570. In such a case, the first spacer layers 540 may be formed as the sacrificial layers 570 are oxidized and expanded in volume. Accordingly, the first spacer layers 540 may be formed in the second openings OP2, respectively.

The first spacer layers 540 may be formed to at least partially fill the second openings OP2, respectively. The thicknesses t of the first spacer layers 540 may be substantially the same as or different from each other. For example, the thicknesses t of the first spacer layers 540 located at different levels may be different from each other. However, the present disclosure is not limited thereto, and the thicknesses t of the first spacer layers 540 located at the same level may also be different from each other. At least one of the sacrificial layers 570 may be partially oxidized. The remaining sacrificial layer 570 may be located between the first spacer layer 540 and the second material layer 513.

The first spacer layers 540 may each include oxide. The first spacer layers 540 may be formed using a wet oxidation process. However, the present disclosure is not limited thereto, and various oxidation processes such as a dry oxidation process may be used. The first spacer layers 540 are formed using an oxidation process and may include no voids. For example, the first spacer layers 440 may be void-free oxide layers.

When the sacrificial layers 570 remaining in the second openings OP2 are oxidized and the first spacer layers 540 are formed to fill all of the second openings OP2, second spacer layers to be described below might not be formed. In other words, only the first spacer layer 540 may be formed as a single layer to be formed in the second opening OP2 through an oxidation process.

Referring to FIG. 5E, a first oxide layer 550A may be formed. For example, a first oxide layer 550A may be formed in the second openings OP2. The first oxide layer 550A may be formed along the profiles of the first opening OP1 and the second openings OP2. The first oxide layer 550A may be formed using a deposition process. For example, the first oxide layer 550A may be formed by an atomic layer deposition (ALD) method. However, the present disclosure is not limited thereto and various deposition processes may be used. In such a case, heat treatment may also be performed together. The first oxide layer 550A may include an insulating material such as oxide or silicon oxide. For example, the first oxide layer 550A may include silicon oxide.

Referring to FIG. 5F, the barrier layer 530 or the first oxide layer 550A formed in the first opening OP1 may be removed by an etching process. For example, the first oxide layer 550A may be partially etched. In other words, a portion of the first oxide layer 550A formed in the first opening OP1 may be etched. When the first oxide layer 550A is etched, a portion of the barrier layer 530 formed in the first opening OP1 may be etched. Furthermore, when the first oxide layer 550A formed in the first opening OP1 is etched, a portion of the first oxide layer 550A formed in the second openings OP2 may be etched.

Referring to FIG. 5G, a second oxide layer 550B may be formed. For example, the second oxide layer 550B may be formed in the second openings OP2. When the second oxide layer 550A is formed, voids may be formed in the second openings OP2. The second oxide layer 550B may be formed using a deposition process. For example, the second oxide layer 550B may be formed by an atomic layer deposition ALD method. However, the present disclosure is not limited thereto and various deposition processes may be used. Accordingly, a second oxide layer including voids may be formed by depositing the second oxide layer on an etched surface of the first oxide layer 550A. The second oxide layer 550B may include an insulating material such as oxide or silicon oxide. For example, the second oxide layer 550B may include silicon oxide.

When the second oxide layer 550B is deposited after the first oxide layer 550A is deposited and etched, the size of the void V may be reduced compared to a case where the second opening OP2 is filled with only the first oxide layer 550A, and the second oxide layer 550B may be formed as a void-free oxide layer. For example, by etching the first oxide layer 550A before the second oxide layer 550B is deposited, a passage through which a deposition gas flows into the second openings OP2 through the first openings OP1 may be secured. Therefore, the inflow of the deposition gas into the second openings OP2 may be increased, and the size of the void V may be reduced or the second oxide layer 550B may be formed as a void-free oxide layer while the second oxide layer 550B is deposited in the second openings OP2. However, the present disclosure is not limited thereto, and the second oxide layer 550B may be additionally etched and a third oxide layer may be deposited, or these processes may be repeated to form oxide layers.

Referring to FIG. 5H, the second material layers 513 may be replaced with the third material layers 512. The third material layers 512 may be conductive layers. Thus, a gate structure 510 including alternately stacked first material layers 511 and third material layers 512 may be formed. The conductive layer may include a conductive material such as polysilicon, tungsten, or molybdenum.

Referring to FIG. 5I, the second oxide layer 550B formed in the first opening may be removed. Thus, the second spacer layer 550 may be formed in each of the second openings OP2. At least one of the second spacer layers 550 may include a void V. Thicknesses s of the second spacer layers 550 may be substantially the same as or different from each other. For example, the thicknesses s of the second spacer layers 550 located at different levels may be different from each other. However, the present disclosure is not limited thereto, and the thicknesses s of the second spacer layers 550 located at the same level may also be different from each other.

The second spacer layers 550 may be formed in substantially the same manner or in a manner different from those of the first spacer layers 540. For example, the second spacer layers 550 may be formed using a deposition process, and the first spacer layers 540 may be formed using an oxidation process. In such a case, the first spacer layers 540 may be formed by an oxidation process and may include no voids V, and the second spacer layers 550 may be formed by a deposition process and may include voids V. As another example, the first spacer layers 540 and the second spacer layers 550 may be formed using an oxidation process. In such a case, the first spacer layers 540 and the second spacer layers 550 may be formed by an oxidation process and may include no voids V. In other words, the spacer layers 540 and 550 may be formed as void-free oxide layers.

Subsequently, a third opening OP3 may be formed. The third opening OP3 connected to the first opening OP1 may be formed by selectively removing the buffer layer 520. For example, the third opening OP3 may be formed after the upper buffer layer 520A and the lower buffer layer 520A are sequentially removed. The uppermost third material layer 512 of the step structure SR may be exposed through the third opening OP3.

When the third opening OP3 is formed, the spacer layers 540 and 550 may be partially etched. For example, when the third opening OP3 is formed, the second spacer layers 550 may be etched and at least one of the voids V included in the second spacer layers 550 may be exposed. However, in an embodiment, it may be possible to prevent the third material layers 512 from being exposed by the first spacer layers 540 including no voids V. Accordingly, in an embodiment, the distance d between the void V and the third material layer 512 may be secured by the first spacer layer 540.

An oxide layer formed by an oxidation method and an oxide layer formed by a deposition method may have different physical properties such as density and etching rate. For example, the etching rate of the first spacer layer 540 may be lower than that of the second spacer layer 550. Therefore, in an embodiment, even though the second spacer layers 550 are exposed, since the etching rate of the first spacer layer 540 is low, it is possible to prevent, minimize, or reduce exposure of the third material layers 512.

Referring to FIG. 5J, a contact plug 560 may be formed. For example, the contact plug 560 including a pillar 560A formed in the first opening OP1 and a protrusion 560B formed in the third opening OP3 may be formed. The protrusion 560B and the uppermost third material layer 512 of the step structure SR may be electrically connected to each other. The contact plug 560 may include a conductive material such as tungsten or metal.

Although not illustrated in FIG. 5J, when the third opening OP3 is formed in FIG. 5i, at least one of the voids V included in the second spacer layers 550 is exposed, so that the contact plug 560 may include an additional protrusion. The additional protrusion may be formed in the second spacer layers 550.

Also, although not illustrated in FIG. 5J, a support may be formed before the contact plugs 560 are formed. In an embodiment, the support may prevent, minimize, or reduce the inclination of the gate structure 510 when the third material layers 512 or the contact plugs 560 are formed during the manufacturing process. The support may include an insulating material such as oxide.

According to the process described above, the first spacer layers 540 may be formed by an oxidation process, and the second spacer layers 550 may be formed by a deposition process. Accordingly, the spacer layers 540 and 550 having different physical properties, presence or absence of voids V, or etching rates may be formed in different manners.

Even though at least one of the second spacer layers 550 includes a void V, the first spacer layers 540 each include no void V and the etching rate of the first spacer layer 540 is lower than that of the second spacer layer 550. Therefore, in an embodiment, even when the second spacer layers 550 are exposed during the manufacturing process, it may be possible to prevent, minimize, or reduce exposure of the third material layers 512 by the first spacer layers 540.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including insulating layers and conductive layers that are alternately stacked;
a contact plug extending in a stacking direction of the insulating layers through the gate structure;
first spacer layers each located between the conductive layers and the contact plug; and
second spacer layers each located between the contact plug and the first spacer layers.

2. The semiconductor device of claim 1, wherein the second spacer layers each include a void.

3. The semiconductor device of claim 1, wherein the first spacer layers are void-free oxide layers.

4. The semiconductor device of claim 1, wherein the first spacer layers or the second spacer layers each include silicon oxide.

5. The semiconductor device of claim 1, wherein the contact plug includes a pillar and a first protrusion protruding from the pillar.

6. The semiconductor device of claim 5, wherein the gate structure includes a step structure for exposing at least one of the conductive layers, and the pillar passes through an uppermost conductive layer exposed by the step structure.

7. The semiconductor device of claim 6, wherein the first protrusion is connected to a top surface of the uppermost conductive layer exposed by the step structure.

8. The semiconductor device of claim 5, further comprising:
a second protrusion located in the second spacer layers and protruding from the pillar.

9. The semiconductor device of claim 1, further comprising:
barrier layers located between the conductive layers and the first spacer layers, respectively.

10. The semiconductor device of claim 9, wherein the barrier layers each include oxide or nitride.

11. The semiconductor device of claim 1, wherein the first spacer layers located at different levels have different thicknesses.

12. The semiconductor device of claim 1, wherein the second spacer layers located at different levels have different thicknesses.

13. The semiconductor device of claim 1, further comprising:
sacrificial layers located between the first spacer layers and the conductive layers, respectively.

14. The semiconductor device of claim 13, wherein the sacrificial layers each include amorphous silicon.

15. A method of manufacturing a semiconductor device, the method comprising:
forming a stack including first material layers and second material layers that are alternately stacked;
forming a first opening extending in a stacking direction of the first material layers through the stack;
forming second openings connected to the first opening by etching the second material layers;
forming first spacer layers in the second openings, respectively;
forming second spacer layers in the second openings, respectively; and
forming a contact plug in the first opening.

16. The method of claim 15, wherein the forming of the first spacer layers comprises:
forming sacrificial layers in the second openings, respectively;
forming the first spacer layers by oxidizing the sacrificial layers.

17. The method of claim 16, wherein the first spacer layers are formed as the sacrificial layers are oxidized and expanded in volume.

18. The method of claim 16, wherein the forming of the sacrificial layers comprises:
forming a sacrificial material in the first opening and the second openings; and
etching the sacrificial material so that a portion of the sacrificial material formed in the first opening is removed.

19. The method of claim 16, wherein the sacrificial layers each include amorphous silicon.

20. The method of claim 15, wherein the first spacer layers are void-free oxide layers.

21. The method of claim 15, wherein the forming of the second spacer layers comprises:
forming a first oxide layer in the second openings;
partially etching the first oxide layer; and
forming a second oxide layer in the second openings.

22. The method of claim 21, wherein, in the forming of the second oxide layer, the second oxide layer including a void is formed by depositing the second oxide layer along an etched surface of the first oxide layer.

23. The method of claim 15, wherein the first spacer layers or the second spacer layers each include silicon oxide.

24. The method of claim 15, further comprising:
forming a step structure for exposing at least one of the second material layers; and
forming a buffer layer on the step structure.

25. The method of claim 24, wherein the forming of the contact plug comprises:
forming a third opening by removing the buffer layer through the first opening; and
forming the contact plug including a pillar located in the first opening and a protrusion located in the third opening.
